(19) United States
(12) Patent Application Publication
(10) Pub. No.: US 2017/0053783 A1
(43) Pub. Date: Feb. 23, 2017

(54) SEMICONDUCTOR APPARATUS AND CLEANING METHOD FOR THE SEMICONDUCTOR APPARATUS

(71) Applicant: Taiwan Semiconductor Manufacturing Co., Ltd, Hsin-Chu (TW)

(72) Inventors: Yin-Bin TSENG, Hsinchu City (TW); Po-Hsiung LEU, Taoyuan City (TW); Ding-I LIU, Hsinchu City (TW); Jyh-Nan LIN, Hsinchu City (TW); Yu-Ying LU, Zhubei City (TW)

(21) Appl. No.: 14/832,182

(22) Filed: Aug. 21, 2015

(51) Int. Cl. H01J 37/32; C23C 16/50; C23C 16/44; C23C 14/24

(52) U.S. Cl. CPC H01J 37/32862; C23C 14/24; C23C 16/50; C23C 16/4412; H01J 37/32715; H01J 37/32834; H01J 37/32082; H01J 2237/332; H01J 2237/3321

(57) ABSTRACT

A semiconductor apparatus is provided. The semiconductor apparatus includes a process chamber, a wafer chuck disposed in the process chamber, and an exhaust device. The exhaust device includes an exhaust tube that communicates with the process chamber, and a valve mechanism installed on the exhaust tube and configured to control the flow rate in the exhaust tube. The semiconductor apparatus further includes a cleaning-gas-supply device including a first cleaning tube that communicates with the process chamber, and a second cleaning tube that communicates with the exhaust device. When a cleaning process is performed, the cleaning-gas-supply device supplies a cleaning gas into the process chamber via the first cleaning tube, and into the valve mechanism via the second cleaning tube.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a wafer, and patterning the various material layers using a lithography process to form circuit components and elements thereon. Many integrated circuits are typically manufactured on a single wafer, and individual dies on the wafer are singulated by sawing between the integrated circuits along a scribe line. The individual dies are typically packaged separately, in multi-chip modules, or in other types of packaging, for example.

In forming multi-level integrated circuit devices, a major portion of the manufacturing cycle involves chemical vapor deposition (CVD), for example plasma enhanced CVD (PECVD) and high density plasma CVD (HDP-CVD), to deposit material layers on wafers by a plasma apparatus. In particular, the depositing of oxide insulating layers, also referred to as inter-metal dielectric (IMD) layers, is performed several times in the formation of a multi-level integrated circuit device. However, materials are also deposited on the plasma chamber, some tubes and valves of the plasma apparatus, and the materials may fall on subsequent wafers.

Although existing devices for a plasma apparatus have been generally adequate for their intended purposes, they have not been entirely satisfactory in all respects. Consequently, it would be desirable to provide a solution for improving the plasma apparatus and the cleaning method of the plasma apparatus.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIG. 1 is a schematic view of a plasma apparatus 1 in accordance with some embodiments of the disclosure.

FIG. 2 is a flow chart of a cleaning method for a plasma apparatus 1 in accordance with some embodiments of the disclosure.

FIGS. 3A to 3B are schematic views of a plasma apparatus 1 during an intermediate stage of a cleaning method in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

A semiconductor apparatus and a cleaning method for semiconductor apparatus are provided. In some embodiments, the semiconductor apparatus is a plasma apparatus. The contaminants in a process chamber and an exhaust device of the semiconductor apparatus can be removed by a cleaning-gas-supply device. Moreover, the time required for cleaning the semiconductor apparatus is decreased.

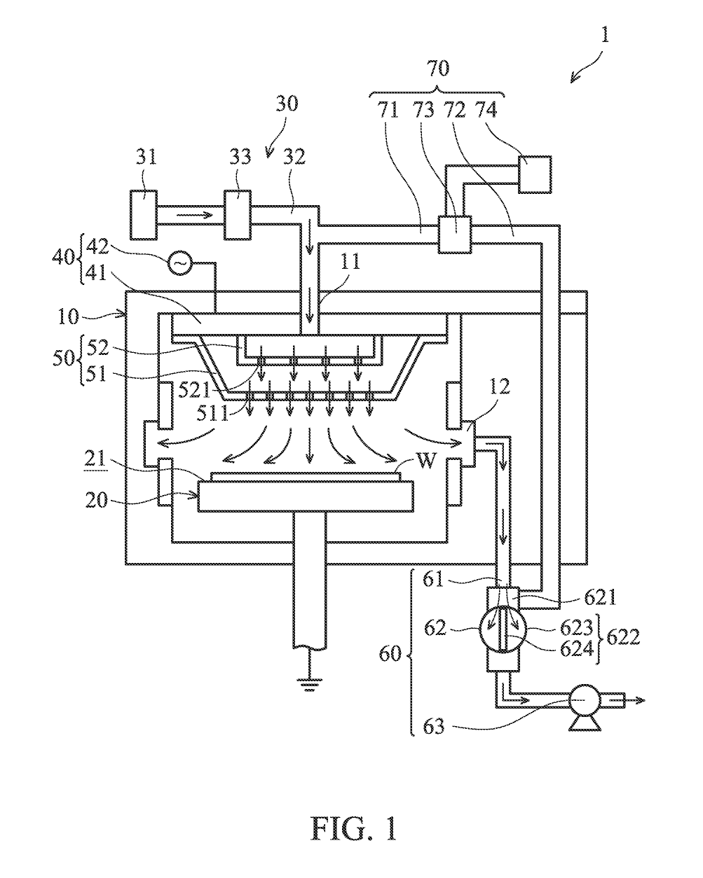

FIG. 1 is a schematic view of a plasma apparatus 1 in accordance with some embodiments of the disclosure. The plasma apparatus 1 is configured to perform a semiconductor manufacturing process on wafers W1. In some embodiments, the semiconductor manufacturing process is a chemical vapor deposition (CVD) process, a physical vapor deposition (PVD) process, an etching process, or a sputtering deposition process.

In some embodiments, the plasma apparatus 1 is a chemical vapor deposition (CVD) plasma apparatus. The plasma apparatus 1 is configured to perform a chemical vapor deposition (CVD) process on the wafer. The plasma apparatus 1 is configured to forming insulation films, such as silicon oxide (SiO), silicon nitride (SiN), silicon oxide carbide (SiOC) and silicon carbide (SiC), and conductive films, such as aluminum (Al) alloy, tungsten silicide (WSi) or titanium nitride (TiN), on wafer W1.

In some embodiments, the wafer W1 is a plate structure. The wafer W1 is a semiconductor substrate including silicon. Alternatively or additionally, the wafer includes another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP.

In some embodiments, the wafer W1 includes a number of conductive and insulation films (not shown in Figures). The conductive and insulation films may include an insulator or a conductive material. For example, the conductive material includes a metal such as aluminum (Al), copper (Cu), tungsten (W), nickel (Ni), titanium (Ti), gold (Au), platinum (Pt), or an alloy of the metals. The insulator material includes silicon oxide or silicon nitride.

The plasma apparatus 1 includes a process chamber 10, a wafer chuck 20, a reaction-gas-supply device 30, a radio frequency device 40, a gas distribution device 50, an exhaust device 60, and a cleaning-gas-supply device 70. In some embodiments, the process chamber 10 is a plasma reactor chamber.

The wafer chuck 20 is disposed in the process chamber 10. The wafer chuck 20 is configured to support the wafer W1. The wafer chuck 20 and the wafer W1 is located at the bottom of the process chamber 10. In some embodiments, the wafer chuck 20 is an electrostatic chuck. The wafer chuck 20 has a supporting surface 21 parallel to a horizontal plane, and faces the gas distribution device 50. The wafer W1 is in contact with the supporting surface 21.

The reaction-gas-supply device 30 is configured to supply reaction gases into the process chamber 10. In some embodiments, the reaction gases include tetra-ethoxy-silane (TEOS) and oxygen. TEOS and oxygen are used to form an oxide layer on the wafer W1.

The reaction-gas-supply device 30 includes a reaction-gas container 31, a gas-supply tube 32, and a reaction-gas-supply element 33. The reaction-gas container 31 is configured to store the reaction gases. The gas-supply tube 32 communicates with the reaction-gas container 31 and the process chamber 10. In some embodiments, one end of the gas-supply tube 32 is connected to the reaction-gas container 31. The other end of the gas-supply tube 32 is connected to an inlet 11 of the process chamber 10. In some embodiments, the inlet 11 is located at the top of the process chamber 10. The inlet 11 faces the wafer chuck 20, and is located above the center of the supporting surface 21.

The reaction-gas-supply element 33 is installed on the gas-supply tube 32. The reaction-gas-supply element 33 is configured to control the flow rate of the reaction gas in the gas-supply tube 32. In some embodiments, the reaction-gas-supply element 33 is a valve or a pump.

The radio frequency device 40 is configured to generate an electric field in the process chamber 10 to excite the reaction gas into plasma. The radio frequency device 40 is located at the top of the process chamber 10, and located over the wafer chuck 20. The radio frequency device 40 includes an electrode 41 and a radio frequency power 42. The electrode 41 is located over the gas distribution device 50. In some embodiments, the electrode 41 is a plate structure parallel to the supporting surface 21. The area of the main surface of the electrode 41 corresponds to the area of the supporting surface 21 of the wafer chuck 20.

The radio frequency power 42 is electrically connected to the electrode 41. The radio frequency power 42 element provides radio frequency energy to the electrode 41. In some embodiments, the wafer chuck 20 is as another electrode 41 of the radio frequency device 40. The radio frequency power 42 is electrically connected to the wafer chuck 20, and the radio frequency power 42 provides radio frequency energy to the wafer chuck 20. In some embodiments, the wafer chuck 20 is grounded.

In some embodiments, the reaction gas (plasma source gas) may be remotely excited outside the process chamber 10 in a waveguide portion prior to entering into the process chamber 10 in a downstream plasma process, for example the reaction gases excited by a microwave source e.g., 2.45 GHz in a waveguide portion upstream from the process chamber 10.

The gas distribution device 50 is disposed in the process chamber 10, and configured to distribute the reaction gas in the process chamber 10. In some embodiments, the gas distribution device 50 is located at the top of the process chamber 10. The gas distribution device 50 is located between the electrode 41 and the wafer chuck 20.

The gas distribution device 50 includes a first shower plate 51 located over the wafer chuck 20. As shown in FIG. 1, the first shower plate 51 is located between the wafer chuck 20 and the first electrode 41. The first shower plate 51 is parallel to the supporting surface 21. In some embodiments, the area of the main surface of the first shower plate 51 corresponds to the area of the supporting surface 21 of the wafer chuck 20.

The first shower plate 51 includes first dispensing holes 511 for the reaction gas to pass through. In some embodiments, the first dispensing holes 511 are arranged in an array. By the first dispensing holes 511, the reaction gas uniformly flows toward the wafer W1 or wafer chuck 20.

In some embodiments, the gas distribution device 50 further includes a second shower plate 52 located over the first shower plate 51. As shown in FIG. 1, the second shower plate 52 is located between the first shower plate 51 and the first electrode 41. The second shower plate 52 is parallel to the supporting surface 21, and separated from the first shower plate 51. The second shower plate 52 includes second dispensing holes 522 for the reaction gas to pass through. In some embodiments, the second dispensing holes 522 are arranged in an array.

The reaction gas flows uniformly through the second dispensing holes 522 toward the first dispensing holes 511. Therefore, the uniformity of the reaction gas flowing toward the wafer W1 or wafer chuck 20 is improved by the second shower plate 52.

In some embodiments, there are more first dispensing holes 511 than second dispensing holes 522. The diameter of the first dispensing holes 511 is greater than the diameter of the second dispensing holes 522.

The exhaust device 60 communicates with the process chamber 10. The exhaust device 60 is configured to remove the gas or plasma in the process chamber 10. The exhaust device 60 includes an exhaust tube 61, a valve mechanism 62, and a vacuum device 63. The exhaust tube 61 communicates with the process chamber 10 and the vacuum device 63. In some embodiments, the process chamber 10 includes an outlet 12 located at a side of the process chamber 10. One end of the exhaust tube 61 is connected to the outlet 12. The other end of the exhaust tube 61 is connected to the vacuum device 63.

The valve mechanism 62 is installed on the exhaust tube 61. The valve mechanism 62 is configured to control the flow rate in the exhaust tube 61. The valve mechanism 62 includes a connection element 621 and a control valve 622. The connection element 621 communicates with the exhaust tube 61 and the control valve 622. In some embodiments, the connection element 621 is a tube structure. The control valve 622 communicates with the connection element 621, and is configured to control the flow rate in the exhaust tube 61.

In some embodiments, the control valve 622 is a throttle valve. The control valve 622 includes a housing 623 and a throttle plate 624. The housing 623 is connected to the connection element 621. The throttle plate 624 is pivoted in the housing 623. The flow rate in the exhaust tube 61 can be adjusted via the rotation of the throttle plate 624. When the throttle plate 624 is in the blocking position, the gas or the plasma in the process chamber 10 is blocked from being exhausted from the process chamber 10. When the throttle plate 624 is in the exhaust position as shown in FIG. 1, the gas or the plasma in the process chamber 10 is exhausted from the process chamber 10.

The vacuum device 63 is installed on the exhaust tube 61. The vacuum device 63 is configured to vacuum the process chamber 10. In some embodiments, the vacuum device 63 is a vacuum pump. The gas or the plasma in the process chamber 10 is drawn by the vacuum device 63.

When the plasma apparatus 1 starts a semiconductor manufacturing process, such as a CVD process, the throttle plate 624 is rotated to the exhaust position, and the vacuum device 63 starts to vacuum the process chamber 10. The process chamber 10 has a plasma operating pressure during the CVD process. The plasma operating pressure is preferably in a range of about 100 mTorr to about 10 Torr, more preferably from about 1 Torr to about 5 Torr.

Moreover, the reaction-gas-supply element 33 supplies the reaction gas into the process chamber 10. The reaction gas flows from the reaction-gas container 31 into the gas-supply tube 32, and the reaction gas flows into the process chamber 10 via the inlet 11. In some embodiments, the flow rate of the reaction gas is in a range from about 100 sccm to about 500 sccm.

Next, the reaction gas flows toward the wafer W1 via the second shower plate 52 and the first shower plate 51 in sequence. Therefore, the reaction gas uniformly flows toward the wafer W1. Moreover, the radio frequency device 40 generates an electric field between the electrode 41 and the wafer W1. The reaction gas is excited into plasma by the electric field. When the plasma hits the wafer W1, the wafer W1 is etched by the plasma, or a film is formed on the wafer W1 by the plasma.

However, after the semiconductor manufacturing process, some contaminants will remain on the inner surface of the process chamber 10, the wafer chuck 20, and the valve mechanism 62.

In some embodiments, the contaminants include organo-silane precursors for depositing organo-silicate glass (OSG) layers, e.g., IMD layers. The organo-silane precursors for example, include methylsilanes, including tetramethylsilane and trimethylsilane. In addition, organo-siloxane precursors such as organo-siloxanes include cyclo-tetra-siloxanes such as tetramethylcyclotetrasiloxane, octamethylcyclotetrasiloxane, and decamethylcyclopentasiloxane. In some embodiments, the contaminants include nitride materials such as silicon nitride and/or silicon oxynitride materials.

The contaminants may fall on a subsequent wafer, causing the yield rate of the subsequent wafer W1 to decrease. For example, the contaminants on the throttle plate 624 can easily float and fall onto the wafer W1 when the throttle plate 624 is rotated. Therefore, the process chamber 10, the wafer chuck 20, and the valve mechanism 62 need cleaning.

The cleaning-gas-supply device 70 is configured to supply cleaning gases to the process chamber 10 and the valve mechanism 62. In some embodiments, the cleaning gases include inert gas, oxygen, nitrogen trifluoride (NF₃) or other suitable gases. In some embodiments, the inert gas is argon, helium or nitrogen. In some embodiments, the cleaning gases include inert gas, oxygen, or nitrogen trifluoride at a concentration that is greater than about 80 volume % or 90 volume %.

The cleaning-gas-supply device 70 includes a first cleaning tube 71, a second cleaning tube 72, a flow valve 73, and a cleaning-gas container 74. The first cleaning tube 71 communicates with the inlet 11 and the flow valve 73. In some embodiments, the first cleaning tube 71 communicates with the gas-supply tube 32. In some embodiments, the second cleaning tube 72 communicates with the connection element 621 or the exhaust tube 61 of the valve mechanism 62.

The flow valve 73 communicates with the cleaning-gas container 74, and the cleaning-gas container 74 is configured to store the cleaning gas. In some embodiments, the flow valve 73 is a flow divider valve. The flow valve 73 is configured to transfer the cleaning gas in the cleaning-gas container 74 into the process chamber 10 via the first cleaning tube 71 and/or the valve mechanism 62 via the first cleaning tube 71. Moreover, the flow valve 73 is configured to adjust the flow rate of the cleaning gas in the first cleaning tube 71 and in the second cleaning tube 72.

In some embodiments, the cleaning gas supplied into the process chamber 10 via the first cleaning tube 71 by the flow valve 73 is different from the cleaning gas supplied into the valve mechanism 62 via the second cleaning tube 72 by the flow valve 73.

In some embodiments, the flow valve 73 can allow the cleaning gas to flow into the process chamber 10 via the first cleaning tube 71 and the valve mechanism 62 via the second cleaning tube 72 at the same time. The flow valve 73 can allow the cleaning gas to flow into the process chamber 10 via the first cleaning tube 71, but block the cleaning gas from flowing into the valve mechanism 62 via the second cleaning tube 72. Moreover, the flow valve 73 can allows the cleaning gas flowing into the valve mechanism 62 via the second cleaning tube 72, but block the cleaning gas from flowing into the process chamber 10 via the first cleaning tube 71.

When the plasma apparatus 1 starts a cleaning process, the throttle plate 624 is rotated to the exhaust position, and the vacuum device 63 starts to vacuum the process chamber 10. Moreover, the flow valve 73 supplies the cleaning gas into the process chamber 10, and the contaminants in the process chamber 10 are removed by the cleaning gas. In some embodiments, the radio frequency device 40 generates an electric field to excite the cleaning gas to plasma. The plasma reacts with the contaminants in the process chamber 10, and the contaminants in the process chamber 10 are removed by the plasma.

Afterwards, the cleaning gas and the plasma is exhausted from the process chamber 10 via the exhaust device 60, and some of the contaminants in the exhaust tube 61 and the valve mechanism 62 are removed by the plasma or the cleaning gas from the process chamber 10.

In some embodiments, the flow valve 73 can allow the cleaning gas to flow into the process chamber 10 via the first cleaning tube 71, but block the cleaning gas from flowing into the valve mechanism 62 via the second cleaning tube 72. However, too much time needed to remove the contaminants from the throttle plate 624.

In some embodiments, the flow valve 73 supplies the cleaning gas into the valve mechanism 62 via the second cleaning tube 72. The contaminants in the valve mechanism 62 are removed by the cleaning gas. In some embodiments, the cleaning gas blows away the contaminants in the valve mechanism 62 by the air pressure of the cleaning gas. In some embodiments, the cleaning gas reacts with the contaminants in the valve mechanism 62 to remove the contaminants.

In addition, the pressure in the process chamber 10 is greater than the pressure in the valve mechanism 62 during the cleaning process. Therefore, the cleaning gas in the exhaust device 60 does not flow back the process chamber 10.

Since the cleaning gas directly flows into the valve mechanism 62 via the second cleaning tube 72, the contaminants on the throttle plate 624 are removed easily and quickly. Therefore, the time required for the cleaning process is decreased.

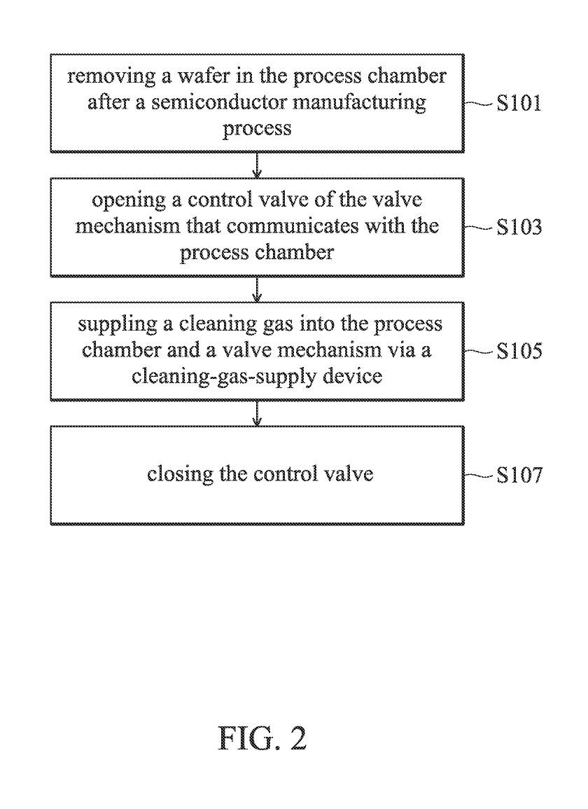

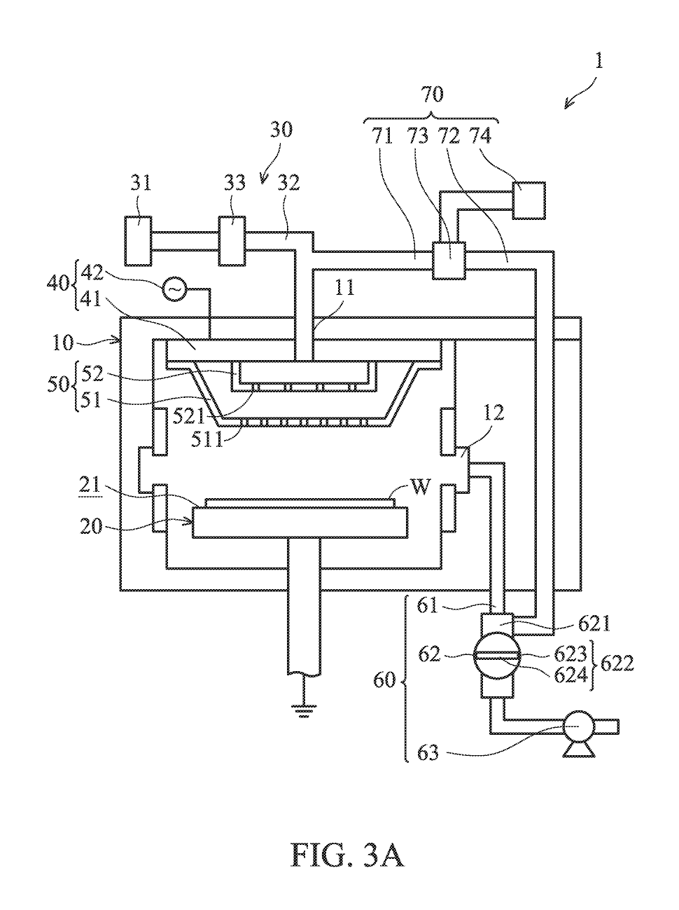

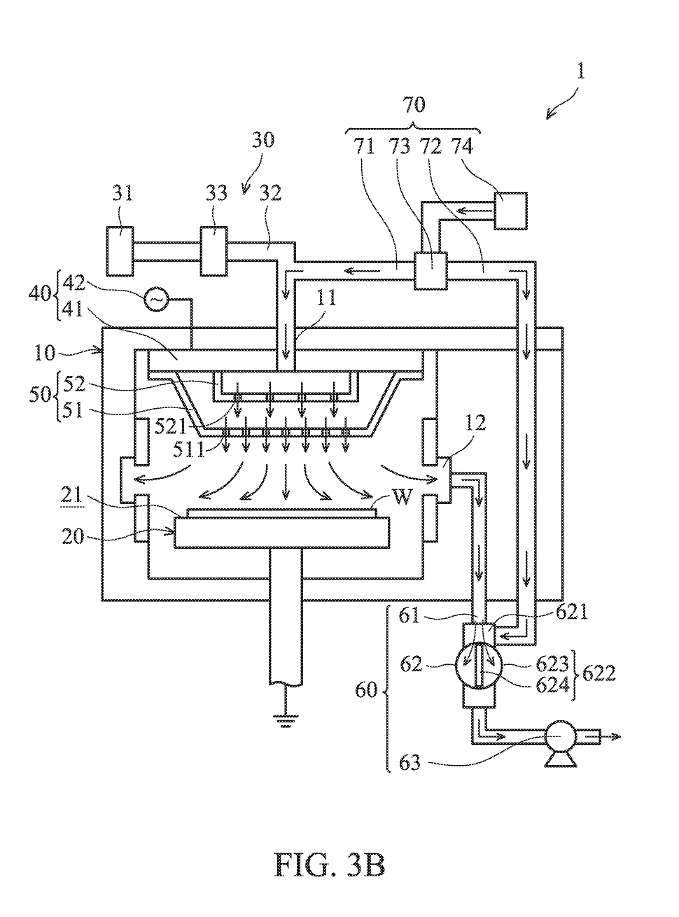

FIG. 2 is a flow chart of a cleaning method for a plasma apparatus 1 in accordance with some embodiments of the disclosure. FIGS. 3A to 3B are schematic views of a plasma apparatus 1 during an intermediate stage of a cleaning method in accordance with some embodiments of the disclosure. The cleaning process can be processed automatically by the plasma apparatus 1 following a semiconductor manufacturing process.

In step S101, a wafer W1 in the process chamber 10 is removed after a semiconductor manufacturing process. In some embodiments, when the wafer W1 is treated by the semiconductor manufacturing process, the reaction-gas-supply device 30 stops supplying the reaction gas, and the radio frequency device 40 stops generating the electric field.

The vacuum device 63 continually draws the reaction gas or plasma in the process chamber 10. In other words, the vacuum device 63 vacuums the process chamber 10 to prevent the wafer W1 from being further treated by the reaction gas or plasma. The vacuum device 63 also vacuums the process chamber 10 to prevent the reaction gas or plasma from flowing out of the process chamber 10 when the wafer W1 is removed from the process chamber 10.

Afterwards, as shown in FIG. 3A, the control valve 622 of the valve mechanism 62 is to be closed and the vacuum device 63 stops vacuuming the process chamber 10. A working gas is supplied into the process chamber 10 to increase the pressure of the process chamber 10 to match the ambient pressure around the plasma apparatus 1. In some embodiments, the valve mechanism 62 is to be closed by the throttle plate 624 rotated to the blocking position. In some embodiments, the working gas is supplied into the process chamber 10 by the cleaning-gas-supply device 70 or the reaction-gas-supply device 30. In some embodiments, the working gas is air or nitrogen. The ambient pressure is about 1 atm.

In some embodiments, the control valve 622 of the valve mechanism 62 is to be closed after the working gas is supplied into the process chamber 10 for further removing the reaction gas or plasma in the process chamber 10.

After the pressure of the process chamber 10 reaches the ambient pressure, the wafer W1 is removed from process chamber 10.

In step S103, as shown in FIG. 3B, after the wafer W1 is removed from the process chamber 10, the control valve 622 of the valve mechanism 62 is opened, and the vacuum device 63 starts to vacuum the process chamber 10. In some embodiments, the valve mechanism 62 is opened by the throttle plate 624 being rotated to the exhaust position.

In step S105, the cleaning gas is supplied into the process chamber 10 and the valve mechanism 62 by the cleaning-gas-supply device 70. The cleaning gas flows through the second dispensing holes 522 of the second shower plate 52 and the first dispensing holes 511 of the first shower plate 51. The cleaning gas uniformly flows toward the wafer chuck 20 by the gas distribution device 50.

In some embodiments, the cleaning gas supplied into the process chamber 10 is different from the cleaning gas supplied into the valve mechanism 62. In some embodiments, the cleaning gas is supplied into the valve mechanism 62 after the cleaning-gas-supply device 70 starts to supply the cleaning gas into the process chamber 10. The flow rate of the cleaning gas flowing into the process chamber 10 is greater than the flow rate of the cleaning gas flowing into the valve mechanism 62.

In some embodiments, the flow rate of the cleaning gas flowing into the process chamber is in a range from about 100 sccm to about 500 sccm. In some embodiments, the flow rate of the cleaning gas flowing into the valve mechanism 62 is in a range from about 50 sccm to about 400 sccm.

Accordingly, the contaminants in the process chamber 10 and the exhaust device 60 can be removed by the cleaning gas. Since the pressure in the process chamber 10 is greater than the pressure in the valve mechanism 62 during the cleaning process, the contaminants in the exhaust tube 61 and the valve mechanism 62 are not drawn back into the process chamber 10.

In some embodiments, an electric field is generated by the radio frequency device 40 to excite the cleaning gas in the process chamber 10 into plasma while the cleaning gas is supplied into the process chamber 10. The plasma operating pressure is preferably in a range of about 100 mTorr to about 10 Torr, more preferably from about 1 Torr to about 5 Torr. Therefore, the contaminants in the process chamber 10 and the exhaust device 60 can be removed or etched by the plasma.

In step S107, the control valve 622 of the valve mechanism 62 is closed. Therefore, the cleaning gas in the exhaust device 60 is prevented from being drawn back into the process chamber 10. The working gas is supplied into the process chamber 10 to increase the pressure of the process chamber 10 to the ambient pressure so that a subsequent wafer W1 can be put into the process chamber 10.

Embodiments of a semiconductor apparatus and a cleaning method for semiconductor apparatus are provided. In some embodiments, the semiconductor apparatus is a plasma apparatus. The contaminants in a process chamber and an exhaust device of the semiconductor apparatus can be removed by a cleaning-gas-supply device automatically following a semiconductor manufacturing process. In addition, the contaminants in a valve mechanism of the exhaust device can be directly removed by the cleaning-gas-supply device. Therefore, the time required for the semiconductor apparatus cleaning process is decreased.

In some embodiments, a semiconductor apparatus is provided. The semiconductor apparatus includes a process chamber, a wafer chuck disposed in the process chamber, and an exhaust device. The exhaust device includes an exhaust tube that communicates with the process chamber, and a valve mechanism installed on the exhaust tube and configured to control the flow rate in the exhaust tube. The semiconductor apparatus further includes a cleaning-gas-supply device including a first cleaning tube that communicates with the process chamber, and a second cleaning tube that communicates with the exhaust device. When a cleaning process is performed, the cleaning-gas-supply device supplies a cleaning gas into the process chamber via the first cleaning tube, and into the valve mechanism via the second cleaning tube.

In some embodiments, a plasma apparatus is provided. The semiconductor apparatus includes a process chamber, a wafer chuck disposed in the process chamber, and an exhaust device. The exhaust device includes an exhaust tube that communicates with the process chamber, and a valve mechanism. The valve mechanism includes a connection element that communicates with the exhaust tube, and a control valve that communicates with the connection element and is configured to control the flow rate in the exhaust tube. The semiconductor apparatus further includes a cleaning-gas-supply device including a first cleaning tube that communicates with the process chamber, and a second cleaning tube that communicates with the connection element. When a cleaning process is performed, the cleaning-gas-supply device supplies a cleaning gas into the process chamber via the first cleaning tube, and into the control valve via the second cleaning tube.

In some embodiments, a cleaning method for a plasma apparatus is provided. The cleaning method includes removing a wafer in the process chamber after a semiconductor manufacturing process. The cleaning method further includes suppling a cleaning gas into the process chamber and a valve mechanism by a cleaning-gas-supply device. The pressure in the process chamber is greater than the pressure in the valve mechanism.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor apparatus, comprising:
a process chamber;
a wafer chuck disposed in the process chamber;
an exhaust device comprising:
an exhaust tube that communicates with the process chamber; and
a valve mechanism installed on the exhaust tube, configured to control flow rate in the exhaust tube; and
a cleaning-gas-supply device, comprising:
a first cleaning tube that communicates with the process chamber; and
a second cleaning tube that communicates with the exhaust device;
wherein when a cleaning process is performed, the cleaning-gas-supply device supplies a cleaning gas into the process chamber via the first cleaning tube, and into the valve mechanism via the second cleaning tube.

2. The semiconductor apparatus as claimed in claim 1, wherein the pressure in the process chamber is greater than the pressure in the valve mechanism during the cleaning process.

3. The semiconductor apparatus as claimed in claim 1, further comprising a reaction-gas-supply device configured to supply a reaction gas into the process chamber.

4. The semiconductor apparatus as claimed in claim 3, further comprising a radio frequency device configured to generate an electric field in the process chamber to excite the reaction gas into plasma.

5. The semiconductor apparatus as claimed in claim 3, further comprising a gas distribution device, disposed in the process chamber, configured to distribute the reaction gas in the process chamber.

6. The semiconductor apparatus as claimed in claim 5, wherein the gas distribution device comprises a first shower plate located over the wafer chuck, and the first shower plate comprises a plurality of first dispensing holes for the reaction gas to pass through.

7. The semiconductor apparatus as claimed in claim 6, wherein the gas distribution device further comprises a second shower plate located over the first shower plate, and the second shower plate comprises a plurality of second dispensing holes for the reaction gas to pass through, wherein there are more first dispensing holes than the second dispensing holes.

8. The semiconductor apparatus as claimed in claim 1, wherein the exhaust device further comprises a vacuum device, installed on the exhaust tube, configured to vacuum the process chamber.

9. A plasma apparatus, comprising:
a process chamber;
a wafer chuck disposed in the process chamber;
an exhaust device comprising:
an exhaust tube that communicates with the process chamber; and
a valve mechanism comprising:
a connection element that communicates with the exhaust tube;
a control valve that communicates with the connection element, configured to control flow rate in the exhaust tube; and
a cleaning-gas-supply device, comprising:
a first cleaning tube that communicates with the process chamber; and
a second cleaning tube that communicates with the connection element;
wherein when a cleaning process is performed, the cleaning-gas-supply device supplies a cleaning gas into the process chamber via the first cleaning tube, and into the control valve via the second cleaning tube.

10. The plasma apparatus as claimed in claim 9, wherein the control valve is a throttle valve, and comprises a housing connected to the connection element, and a throttle plate pivoted in the housing.

11. The plasma apparatus as claimed in claim 9, wherein the pressure in the process chamber is greater than the pressure in the valve mechanism during the cleaning process.

12. The plasma apparatus as claimed in claim 9, further comprising a reaction-gas-supply device configured to supply a reaction gas into the process chamber.

13. The plasma apparatus as claimed in claim 12, further comprising a radio frequency device configured to generate an electric field in the process chamber to excite the reaction gas into plasma.

14. The plasma apparatus as claimed in claim 12, further comprising a gas distribution device, disposed in the process chamber, configured to distribute the reaction gas in the process chamber.

15. The plasma apparatus as claimed in claim 14, wherein the gas distribution device comprises a first shower plate located over the wafer chuck, and the first shower plate comprises a plurality of first dispensing holes for the reaction gas to pass through.

16. The plasma apparatus as claimed in claim 15, wherein the gas distribution device further comprises a second shower plate located over the first shower plate, and the second shower plate comprises a plurality of second dispensing holes for the reaction gas to pass through, wherein there are more first dispensing holes than the second dispensing holes.

17. The plasma apparatus as claimed in claim 9, wherein the exhaust device further comprises a vacuum device, installed on the exhaust tube, configured to vacuum the process chamber.

18-20. (canceled)

21. A semiconductor apparatus, comprising:
a process chamber;
a wafer chuck disposed in the process chamber;
an exhaust device comprising:
an exhaust tube that communicates with the process chamber; and
a valve mechanism installed on the exhaust tube, configured to control flow rate in the exhaust tube;
a cleaning-gas-supply device, comprising:
a first cleaning tube that communicates with the process chamber; and
a second cleaning tube that communicates with the exhaust device; and
a reaction-gas-supply device, configured to supply a reaction gas into the process chamber, comprising a reaction-gas container configured to store the reaction gas, and a gas-supply tube communicating with the reaction-gas container and the process chamber,
wherein when a cleaning process is performed, the cleaning-gas-supply device supplies a cleaning gas into the process chamber via the first cleaning tube, and into the valve mechanism via the second cleaning tube.

22. The semiconductor apparatus as claimed in claim 21, wherein the pressure in the process chamber is greater than the pressure in the valve mechanism during the cleaning process.

23. The semiconductor apparatus as claimed in claim 21, wherein the first cleaning tube is connected to the gas-supply tube.
